(19) United States
(12) Patent Application Publication
(10) Pub. No.: US 2026/0004821 A1
(43) Pub. Date: Jan. 1, 2026

(54) APPARATUS INCLUDING MEMORY MAT EDGE STRUCTURE

(71) Applicant: MICRON TECHNOLOGY, INC., BOISE, ID (US)

(72) Inventors: Naokazu Murata, Higashihiroshima (JP); Russell A. Benson, Boise, ID (US); Efe S. Ege, Boise, ID (US)

(73) Assignee: MICRON TECHNOLOGY, INC., Boise, ID (US)

(21) Appl. No.: 19/247,064

(22) Filed: Jun. 24, 2025

Related U.S. Application Data
(60) Provisional application No. 63/666,421, filed on Jul. 1, 2024.

(51) Int. Cl. G11C 5/06; G11C 5/10; H10D 64/66

(52) U.S. Cl. CPC G11C 5/063; G11C 5/10; H10D 64/666

(57) ABSTRACT

Some embodiments of the disclosure provide an apparatus comprising a memory mat including a memory cell portion, a dummy portion adjacent to the memory cell portion, and an edge portion adjacent to the dummy portion. The memory cell portion includes a first capacitor structure, a first redistribution layer structure coupled to the first capacitor structure, and a cell contact structure coupled to the redistribution layer structure, and the first capacitor structure is coupled to the cell contact structure by the first redistribution layer structure. The dummy portion includes a second capacitor structure and a second redistribution layer structure coupled to the second capacitor structure. The edge portion includes an outermost capacitor structure and a conductive layer structure coupled to the outermost capacitor structure, and the conductive layer structure is at a position higher than the first and second redistribution layer structures on the semiconductor substrate.

### CROSS-REFERENCE TO RELATED APPLICATIONS

This application claims the filing benefit of U.S. Provisional Application No. 63/666,421, filed Jul. 1, 2024. This application is incorporated by reference herein in its entirety and for all purposes.

### BACKGROUND

High data reliability, high speed of memory access, low power consumption, and reduced chip size are some features that are demanded from a semiconductor memory device, such as a dynamic random-access memory (DRAM). A semiconductor memory device may have a plurality of memory mats on a semiconductor substrate. Each memory mat may include a plurality of memory cells located at intersections of word lines and bit lines. Each memory cell may include a capacitor structure to store data.

### BRIEF DESCRIPTION OF THE DRAWINGS

FIG. 1 depicts an example layout of memory mats of a semiconductor device in a plan view according to an embodiment of the disclosure.

FIG. 2 depicts a part of example mat edge structures of a semiconductor device in an enlarged plan view according to an embodiment of the disclosure.

FIGS. 3A and 3B each depict a part of an example memory mat edge structure of a semiconductor device in a cross-sectional view according to an embodiment of the disclosure.

FIGS. 4A and 4B each depict a part of an example memory mat edge structure of a semiconductor device in a cross-sectional view according to an embodiment of the disclosure.

FIGS. 5A-5L depict example processes of manufacturing an example memory mat edge structure of a semiconductor device in a cross-sectional view according to an embodiment of the disclosure.

FIGS. 6A-6M depict example processes of manufacturing an example memory mat edge structure of a semiconductor device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

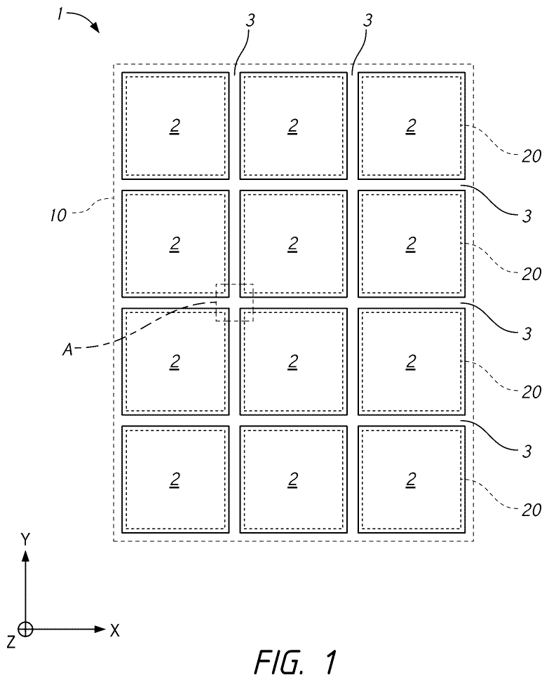

FIG. 1 depicts an example layout of memory mats of a semiconductor device 1 in a plan view according to an embodiment of the disclosure. The semiconductor device 1, such as a dynamic random-access memory (DRAM), includes a plurality of memory mats 2 arranged in a matrix on a surface of a semiconductor substrate 10. Each memory mat 2 has, for example, a rectangular shape in a plan view. The rectangular shape herein may include a square shape. Each memory mat 2 may include a plurality of memory cells arranged in a matrix. Each memory mat 2 includes a memory cell portion 20. The memory cell portion 20 may include at least part of the plurality of memory cells. Each memory cell may include a capacitor to store data. Each memory mat 2 may also include a dummy potion and an edge portion, which will be described in detail below.

Each memory mat 2 may also include a plurality of word lines which are arranged in parallel with each other and extend in a first horizontal direction, which may be an X-axis direction in the drawing. Each memory mat 2 may also include a plurality of bit lines which are arranged in parallel with each and extend in a second horizontal direction, which may be a Y-axis direction in the drawing. The first horizontal direction of the word lines and the second horizontal direction of the bit lines are perpendicular (or substantially perpendicular within reasonable tolerances of fabrication, measurement, etc.) to each other, and may be referred to as a word-line direction and a bit-line direction, respectively. The word lines and the bit lines may be orthogonal (or substantially orthogonal within reasonable tolerances of fabrication, measurement, etc.) to each other. In one instance, the word lines may be arranged in rows, and the bit lines may be arranged in columns. The memory cells may be located at intersections of the word lines (rows) and the bit lines (columns).

The semiconductor device 1 also includes a plurality of peripheral regions 3 surrounding the memory mats 2. The word lines in each memory mat 2 may be coupled to, for example, subword drivers in the peripheral regions 3 outside the memory mat 2 in the word-line direction. The bit lines may be coupled to, for example, sense amplifiers in the peripheral regions 3 outside the memory mat 2 in the bit-line direction. As one example operation, each of the subword drivers may activate an associated one of the word lines in an associated one of the rows. When the associated word line is activated, the plurality of memory cells at the intersections in the associated row are coupled to associated ones of the bit lines in associated columns. When data stored in the capacitors of the memory cells are read to the bit lines, the read data are amplified by associated ones of the sense amplifiers.

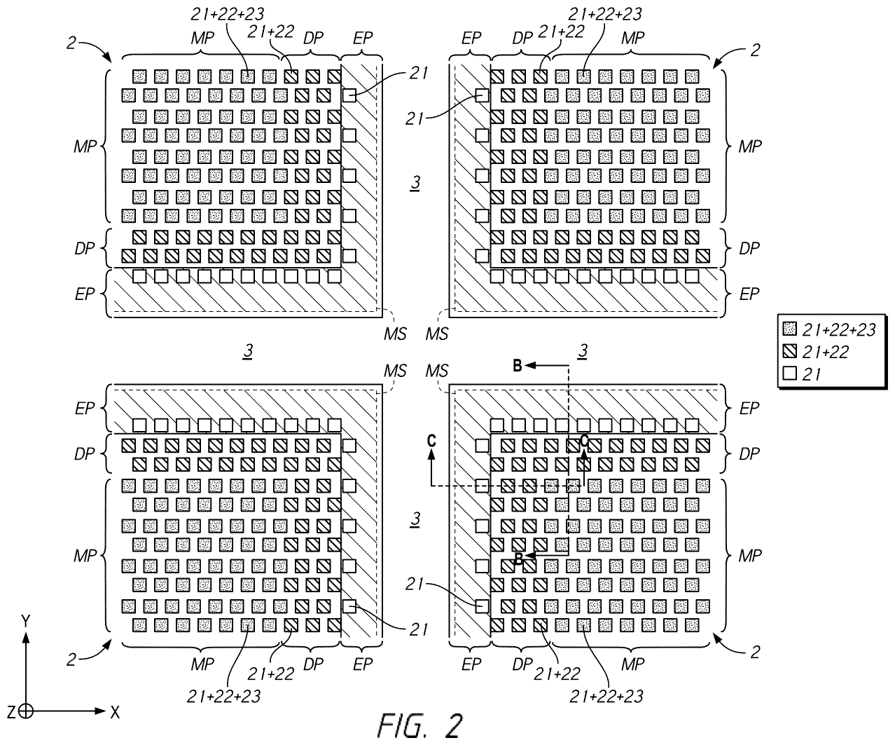

FIG. 2 depicts a part of example memory mat edge structures of a semiconductor device in an enlarged plan view according to an embodiment of the disclosure. The enlarged plan view of FIG. 2 corresponds to part A of the example layout of the memory mats 2 including the peripheral regions 3 of the semiconductor device 1 in FIG. 1. Each memory mat 2 of the rectangular shape has an edge structure along its four edges. The edge structure may also be referred to as a memory mat edge structure herein.

The memory mat 2 includes a memory cell portion MP, a dummy portion DP, and an edge portion EP. The memory cell portion MP may correspond to at least part of the memory cell portion 20 of the memory mat 2 in FIG. 1. The memory cell portion MP is the innermost portion in the memory mat 2 among the memory cell portion MP, the dummy portion DP, and the edge portion EP. The dummy portion DP is provided adjacently to and around a periphery of the memory cell portion MP. The dummy portion DP surrounds the memory cell portion MP. The edge portion EP is provided adjacently to and around a periphery of the dummy potion DP. The edge portion EP surrounds the dummy portion DP.

The memory mat 2 includes a plurality of capacitor structures 21 arranged in a matrix on the semiconductor substrate. The memory cell portion MP includes at least part of or a first group of a plurality of capacitor structures 21, a plurality of redistribution layer (RDL) structures 22, and a plurality of cell contact structures 23, which are arranged in a matrix on the semiconductor substrate. Each capacitor structure 21 forms at least part of the memory cell to store data by accumulating electric charges therein and to be accessed via the associated word line and bit line during data write and read operations. Each capacitor structure 21 may be a vertical capacitor structure that extends in a vertical direction, which may be a Z-axis direction in the drawing. The capacitor structures 21 may be coupled to the respective redistribution layer (RDL) structures 22 and cell contact structures 23 that are provided between the capacitor structures 21 and the semiconductor substrate. Each RDL structure 22 may include a conductive layer structure or a conductive wiring structure that may couple the corresponding capacitor structure 21 and the corresponding cell contact structure 23. Each cell contact structure 23 may include a conductive contact structure that may be coupled to the corresponding RDL structure 22. The RDL structure 22 and the cell contact structure 23 are arranged at the same position as the corresponding capacitor structure 21 in the X and Y-axes plane. In FIG. 2, the capacitor structure 21, the RDL structure 22, and the cell contact structure 23 that are in the same X and Y-axes plane alignment in the memory cell portion MP are depicted with a single square in one hatching style.

The dummy potion DP includes at least another part of or a second group of the plurality of capacitor structures 21 and another plurality of RDL structures 22. Unlike the capacitor structures 21 of the memory cell portion MP, the capacitor structures 21 of the dummy portion DP do not have the ability to store data or to be used during the write and read operations. In FIG. 2, the capacitor structures 21 and the RDL structures 22 in the same X and Y-axes plane alignment in the dummy portion DP are depicted with a single square in another hatching style.

The edge portion EP includes one or more outermost capacitor structures 21 among the plurality of the capacitor structures 21, but does not include the RDL structures 22 and the cell contact structures 23. The outermost capacitor structures 21 are aligned in the outermost row and column of the matrix. In FIG. 2, the outermost capacitor structure 21 in the edge portion EP is depicted with a non-hatched single square. The edge portion EP may also include a moat structure MS that may be arranged, for example, adjacently to and surrounding the dummy portion DP. The moat structure MS may be coupled to the outermost capacitor structures 21. In some instances (not separately depicted in FIG. 2), the edge portion EP may also include the second outermost capacitor structures 21 in the second outermost row and column next to the outermost row and column. In such a case, the moat structure MS may be coupled to both the outermost capacitor structures 21 and the second outermost capacitor structures 21. The moat structure MS will be described in detail below.

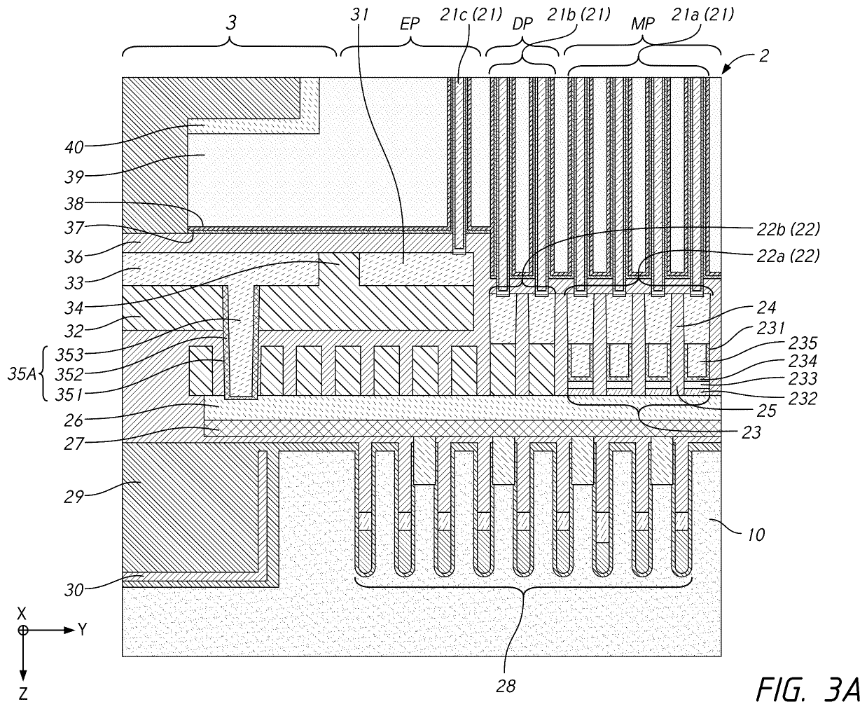

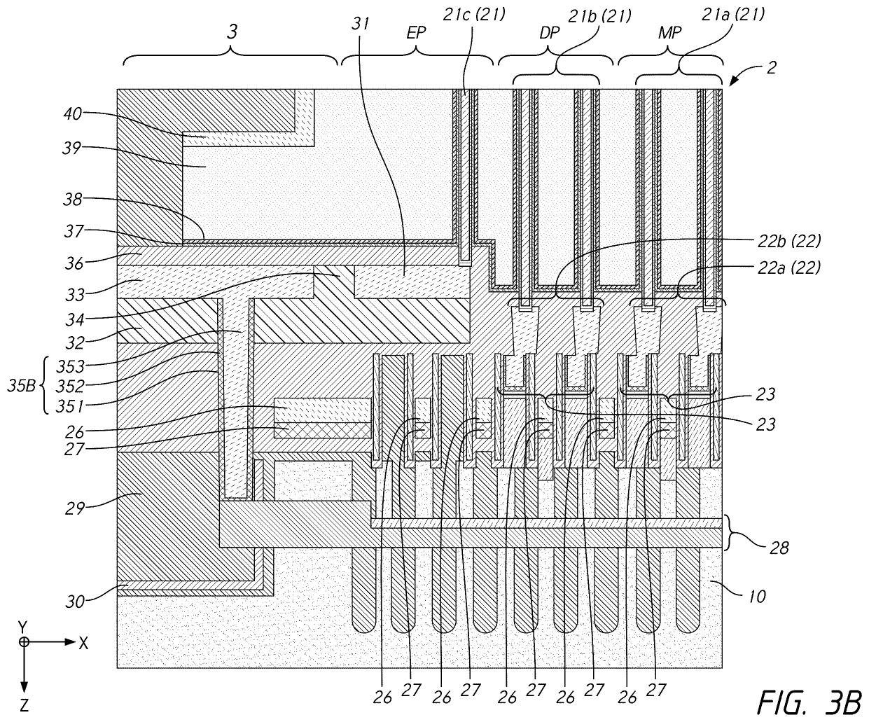

FIGS. 3A and 3B each depict a part of an example memory mat edge structure of a semiconductor device in a cross-sectional view according to an embodiment of the disclosure. The cross-sectional view of FIG. 3A corresponds to B-B line in FIG. 2. The cross-sectional view of FIG. 3B corresponds to C-C line in FIG. 2. The size of each portion and element in FIGS. 3A and 3B may not accurately reflect the size of each corresponding portion and element in FIG. 2. The memory mat edge structure that is the edge structure of the memory mat 2 in FIGS. 3A and 3B includes a memory cell portion MP, a dummy portion DP adjacent to and surrounding the memory cell portion MP, and an edge portion EP adjacent to and surrounding the dummy portion DP, which correspond to at least part of the memory cell portion MP, at least part of the dummy portion DP, and at least part of the edge portion EP in FIG. 2, respectively. The cross-sectional view also shows a part of the peripheral region 3 surrounding the memory mat 2.

The memory cell portion MP includes a first group of capacitor structures 21a, a first group of RDL structures 22a, and a group of cell contact structures 23. In the memory cell portion MP, the first group of capacitor structures 21a is coupled to the group of cell contact structures 23 by the first group of RDL structures 22a.

The first group of capacitor structures 21a among the plurality of capacitor structures 21 is provided at a position corresponding to the first group of RDL structures 22a. Each capacitor structure 21a is a vertical capacitor structure extending vertically in the Z-axis direction, and at least a bottom part thereof is coupled to the corresponding RDL structure 22a. The vertical capacitor structure may include a cylinder-like structure. The vertical capacitor structure may include a multi-layer structure of one or more conductive layers/films, such as a titanium nitride (TiN) layer, and one or more insulating layers/films, such as an oxide layer. The multi-layer structure is not limited to the one illustrated in FIG. 2, and may include other layers, films, and the like as appropriate.

The first group of RDL structures 22a among the plurality of RDL structures 22 is provided at a position corresponding to the group of cell contact structures 23. The RDL structures 22a each extend in the Z-axis direction, and are arranged adjacent to each other at positions corresponding to the respective cell contact structures 23. At least a bottom part of each RDL structure 22a is coupled to the corresponding cell contact structure 23. Each RDL structure 22a may include a conductive material, such as tungsten (W). In the example, the RDL structures 22a are electrically independent of each other by respective insulating structures 24 that fill spaces between the neighboring RDL structures 22a. The insulating structures 24 may include an insulating material, such as a nitride. In one instance, an insulating layer may be provided by, for example, a deposition process, on an underlying layer which includes the cell contact structures 23, and the RDL structures 22a may be formed in the insulating layer by, for example, a damascene process, leaving the insulating structures 24 therebetween. The deposition process and the damascene process will be described in detail below.

Each cell contact structure 23 may include a mutli-layer conductive structure formed in a contact hole 231. As one example, the multi-layer conductive structure includes a poly thin film layer or film 232 at a bottom of the contact hole 231, a cobalt silicide (CoSi₂) thin film layer 233 on the poly thin film layer 232, a titanium nitride (TiN) thin film layer 234 on the CoSi₂ thin film layer 233 and on side surfaces of the contact hole 231, and a tungsten (W) layer 235 on the TiN thin film layer 234 and filling the contact hole 231. The multi-layer structure is not limited to the illustrated example, and may include other layers, films, and the like as appropriate. In the example, similarly to the RDL structures 22a, the cell contact structures 23 are separated from each other by respective insulating structures 25 that fill spaces between the neighboring cell contact structures 23. The insulating structures 25 may include an insulating material, such as a nitride. The bit lines 26 each extend in the Y-axis direction (that is the column direction in the plan view of FIG. 1 or FIG. 2) as shown in FIG. 3A, and are arranged in parallel with each other in the X-axis direction as shown in FIG. 3B. The bit lines 26 may include a conductive material, such as tungsten (W).

In the example, the bit lines 26 are provided on conductive layers 27. The conductive layers 27 are provided above a plurality of word-line (WL) structures 28. The conducive layers 27 each extend in the Y-axis direction as shown in FIG. 3A, and are arranged adjacent to each other in the X-axis direction as shown in FIG. 3B. The conductive layers 27 may include a conductive material, such as a titanium nitride (TiN). The WL structures 28 each extend in the X-axis direction (that is the row direction in the plan view of FIG. 1 or FIG. 2) as shown in FIG. 3B, and are arranged in parallel with each other in the Y-axis direction as shown in FIG. 3A. Each WL structure 28 may include a multi-layer structure of one or more conductive layers/films, such as a TiN layer, and one or more insulating layers/films, such as an oxide layer and a nitride layer, formed in the semiconductor substrate 10. The WL structures 28 and the bit lines 26 are provided orthogonal or substantially orthogonal to each other in the X and Y-axes plane. The multi-layer structure is not limited to the illustrated example, and may include other layers, films, and the like as appropriate. In the example, there may be some other layers, structures, and the like provided in or on the semiconductor substrate 10, such as an insulating layer 29 and another insulating layer 30 with different insulating materials.

The dummy portion DP adjacent to the memory cell portion MP includes a second group of capacitor structures 21b and a second group of RDL structures 22b. The second group of capacitor structures 21b among the plurality of capacitor structures 21 is provided at a position corresponding to the second group of RDL structures 22b. Each capacitor structure 21b includes the same vertical capacitor structure as the capacitor structure 21a, and at least a bottom part thereof is coupled to the corresponding RDL structure 22b. Similarly to the RDL structures 22a in the memory cell portion MP, the RDL structures 22b may be formed in the insulating layer by the damascene process, leaving the insulating structures 24 therebetween which electrically separate the neighboring RDL structures 22b. The RDL structures 22a and 22b may be simultaneously formed in the insulating layer by the same damascene process. Unlike the capacitor structures 21a of the memory cell portion MP, the capacitor structures 21b in the dummy portion DP do not function for the data write and read operations. The capacitor structures 21b may thus be referred to as dummy capacitor structures.

The edge portion EP adjacent to the dummy portion DP includes the outermost capacitor structure 21c and a conductive layer structure 31. The outermost capacitor structure 21c among the plurality of capacitor structure 21 is provided at a position corresponding to the conductive layer structure 31. The outermost capacitor structure 21c is coupled to the conductive layer structure 31. In the example, at least a bottom part of the outermost capacitor structure 21c is coupled to the conductive layer structure 31. The conductive layer structure 31 is provided at a position adjacent to the dummy portion DP in the X and Y-axes plane, and also at a position in the Z-axis direction higher than the first and second groups of RDL structures 22a and 22b of the memory cell and dummy portions MP and DP on the semiconductor substrate 10. In the example, the edge portion EP includes an underlying insulating layer 32, such as an oxide layer, at the same layer level as the RDL structures 22a and 22b, and the conductive layer structure 31 is provided on the underlying insulating layer 32 such that the conductive layer structure 31 is positioned higher than the RDL structures 22a and 22b on the semiconductor substrate 10. In one instance, the conductive layer structure 31 and the RDL structures 22a and 22b may include the same conductive materials, such as tungsten (W). In another instance, the conductive layer structure 31 and the RDL structures 22a and 22b may include different conductive materials. The conductive layer structure 31 may also be referred to as a moat structure. In the case where the memory mat 2 has a rectangular shape as shown in FIG. 1, the memory cell portion MP has the rectangular shape, and then the dummy portion DP surrounds the memory cell portion DP and the conductive layer structure/moat structure 31 of the edge portion EP surrounds the dummy portion DP. For example, the moat structure 31 is provided on the entire periphery of the memory mat 2 as part of the memory mat edge structure. The moat structure 31 separates the memory cell and dummy portions MP and DP where the RDL structures 22a and 22b and the cell contact structures 23 are provided from the rest of the edge portion EP. The moat structure 31 may further be referred to as a moat ring since it is arranged around the memory mat 2. If the moat structure 31 and the RDL structures 22 (22a and 22b) are provided in the same layer above the bit lines 26, then the moat structure 31 and the RDL structures 22 may need to be formed by applying an etching process at least twice, that is double etching, to the same layer with a limited critical dimension margin of the moat structure 31. However, according to the present embodiment, since the moat structure 31 is provided in a layer different from and higher than the RDL structures 22, there is no need for such double etching in the same layer, and thus an issue, such as a short between defective RDL structures 22 and moat structure 31 that may be caused by the double etching, can be effectively avoided during formation of the RDL structures 22 and the moat structure 31 in the different layers. The resultant edge structure of the memory mat 2 and hence the semiconductor device 1 including the memory mat 2 have greater reliability with less deficiencies.

Furthermore, in the example, adjacent to the edge portion EP is the peripheral region 3 surrounding the memory mat 2. The peripheral region 3 includes a conductive layer structure 33. The conductive layer structure 33 is provided at the same layer level as the moat structure 31, but is electrically separated by, for example, a gap 34, from the moat structure 31. The moat structure 31 in the edge portion EP and the conductive layer structure 33 in the peripheral region 3 arc electrically independent of each other by the gap 34. The gap 34 is filled with the same material as the underlying insulating layer 32.

In the example, the peripheral region 3 further comprises conductive contact structures 35A (FIG. 3A) and 35B (FIG. 3B). The conductive contact structures 35A and 35B each may include a conductive via structure. The contact structure 35A and 35B each may include a mutli-layer conductive structure formed in a contact hole (or a via hole) 351. As one example, the multi-layer conductive structure includes a titanium nitride (TiN) thin film layer 352 on surfaces of the contact hole 351, and a tungsten (W) layer 353 on the TiN thin film layer 352 and filling the contact hole 351. The multi-layer structure is not limited to the illustrated example, and may include other layers, films, and the like as appropriate. As shown in FIG. 3A, the conductive contact structure 35A is coupled to the bit line 26 at a lower end thereof and to the conductive layer structure 33 at an upper end thereof. The bit line 26 extends from the memory mat 2 to the peripheral region 3. The conductive contact structure 35A thus couples the bit line 26 to the conductive layer structure 33 in the peripheral region 3. As shown in FIG. 3B, the conductive contact structure 35B is coupled to the WL structure 28 at a lower end thereof and to the conductive layer structure 33 at an upper end thereof. The WL structure 28 extends from the memory mat 2 to the peripheral region 3. The conductive contact structure 35B thus couples the WL structure 28 to the conductive layer structure 33 in the peripheral region 3. The conductive contact structures 35A and 35B may also be referred to as local contact structures.

In the example, there is also an insulating layer 36 provided across the peripheral region 3 and the edge, dummy, and memory cell portions EP, DP and MP of the memory mat 2, covering the surfaces of at least the conductive layer structure 33, the gap 34, the moat structure 31, and the RDL structures 22a and 22b. There is further a stack of an insulating thin film 37 and a conductive thin film 38 on the insulating layer 36, and a polysilicon layer 39 on the stacked films, covering the surface of the insulating layer 36 as well as the side surfaces of the capacitor structures 21a-21c. The polysilicon layer 39 also fills spaces between the neighboring capacitor structures 21a-21c. Still furthermore, another conductive layer 40 is provided on the polysilicon layer 39. The insulating thin film 37 may include an insulating material. The insulating material may be any conventional insulating material as appropriate. The conductive thin film 38 may include a conductive material, such as a tungsten nitride (W₂N). The conductive layer 40 may include a conductive material, such as tungsten (W).

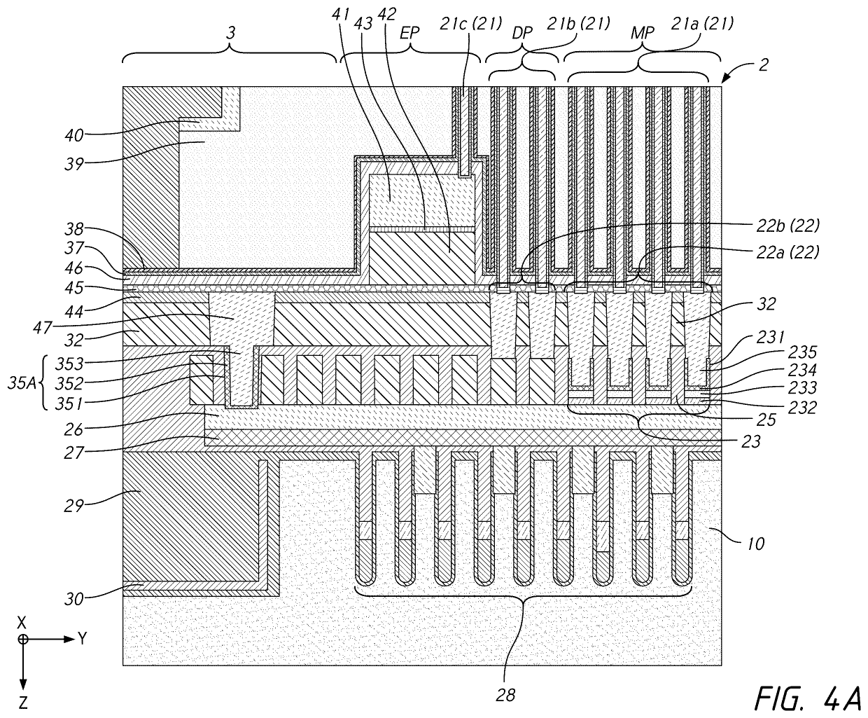

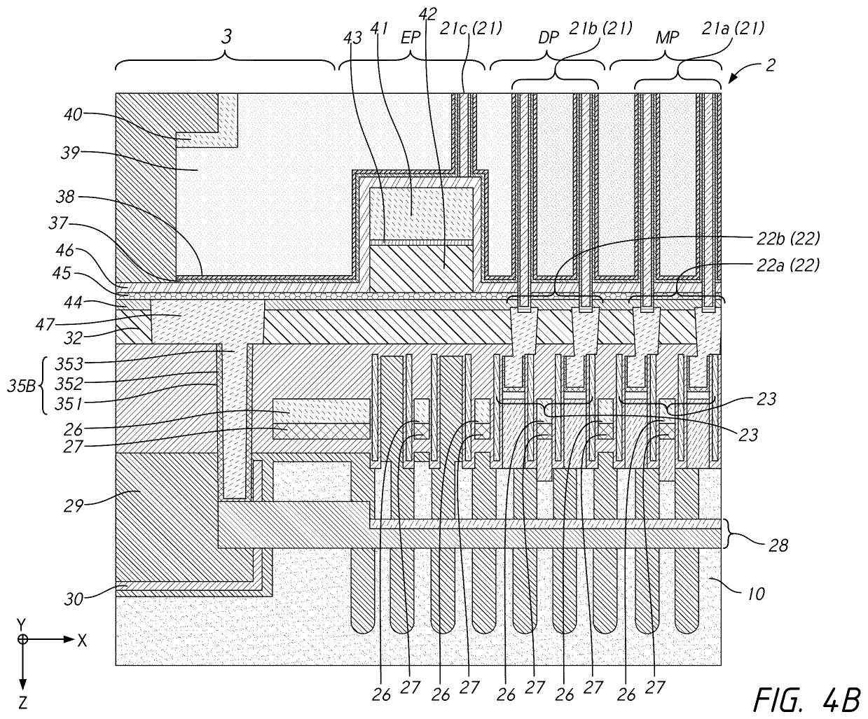

FIGS. 4A and 4B each depict a part of an example memory mat edge structure of a semiconductor device in a cross-sectional view according to an embodiment of the disclosure. The size of each portion and element in FIGS. 4A and 4B may not accurately reflect the size of each corresponding portion and element in FIG. 2. Similarly to the memory mat edge structure in FIGS. 3A and 3B, the edge structure of the memory mat 2 in FIGS. 4A and 4B, includes a memory cell portion MP, a dummy portion DP adjacent to and surrounding the memory cell portion MP, and an edge portion EP adjacent to and surrounding the dummy portion DP, which correspond to at least part of the memory cell portion MP, at least part of the dummy portion DP, and at least part of the edge portion EP in FIG. 2, respectively. The cross-sectional view also shows a part of the peripheral region 3 surrounding the memory mat 2.

The memory cell portion MP, the dummy portion DP, and the edge portion EP of the memory mat edge structure in FIGS. 4A and 4B are the same or substantially the same as the memory cell portion MP, the dummy portion DP, and the edge portion EP of the memory mat edge structure in FIGS. 3A and 3B, respectively, except that the edge portion EP includes a conductive layer structure or a moat structure 41 which is elevated higher than the moat structure 31 (FIGS. 3A and 3B) on the semiconductor substrate 10. As one example, the edge portion EP of the memory mat edge structure in FIGS. 4A and 4B includes an underlying layer structure 42 on the underlying insulating layer 32. More specifically, in the example, an insulating layer 44 (including an insulating material, such as a nitride) and another insulating layer 45 (including an insulating material different from the insulating material of the insulating layer 44) stacked on each other are provided on the underlying insulating layer 32, and the underlying layer structure 42 is formed on the stacked layers 44 and 45 at a predetermined position above the underlying insulating layer 32. The predetermined position may be adjacent to and surrounding the dummy portion DP. Furthermore, there is a middle thin film 43 formed on the underlying layer structure 42, and the moat structure 41 is provided on the middle thin film 43. In this configuration, the moat structure 41 on the middle thin film 43 and the underlying layer structure 42 is at a layer level further higher than the RDL structures 22 (or 22a and 22b) in comparison with the moat structure 31 (FIGS. 3A and 3B). The underlying layer structure 42 may include, for example, an oxide. The middle thin film 43 may include, for example, a titanium nitride (TiN). The moat structure 41 may include, for example, tungsten (W). In the example, surfaces of the moat structure 41, the middle thin film 43 and the underlying layer structure 42 are covered by an insulating layer 46 including an insulating material, such as a nitride. The stacked films 37 and 38 as well as the polysilicon layer 39 and the conductive layer 40 are provided in a similar manner to the example in FIGS. 3A and 3B.

In the example structure of FIGS. 4A and 4B, in the memory cell portion MP and the dummy portion DP, the RDL structures 22a and 22b are separated from each other by the underlying insulating layer 32. In one instance, the underlying insulating layer 32, such as the oxide layer, may be provided by, for example, a deposition process, on another underlying layer which includes the cell contact structures 23, and the RDL structures 22a and 22b are formed in the underlying insulating layer 32 by, for example, a damascene process. At the same time, in the peripheral region 3, one or more conductive layer structures 47 may be formed in the underlying insulating layer 32 by the damascene process. Each conductive layer structure 47 may be a wiring extending in either the X-axis direction or the Y-axis direction in the underlying insulating layer 32. The conductive layer structure 47 may be coupled to the bit line 26 via the local contact structure 35A or to the WL structure 28 via the local contact structure 35B. The deposition process and the damascene process will be described in detail below. According to the present embodiment, since the RDL structures 22 (22a and 22b) and the conductive layer structure 47 may be formed in the same layer by the same process, such as the damascene process, and the moat structure 41 is formed in the layer elevated further higher than the layer of the RDL structures 22, the issue of a short between the conductive structures and the like can be further effectively prevented during the formation of the RDL structures 22 and the moat structure 41 in the different layers. Consequently, a more reliable semiconductor device including the memory mat 2 with the edge structure of the embodiment can be achieved.

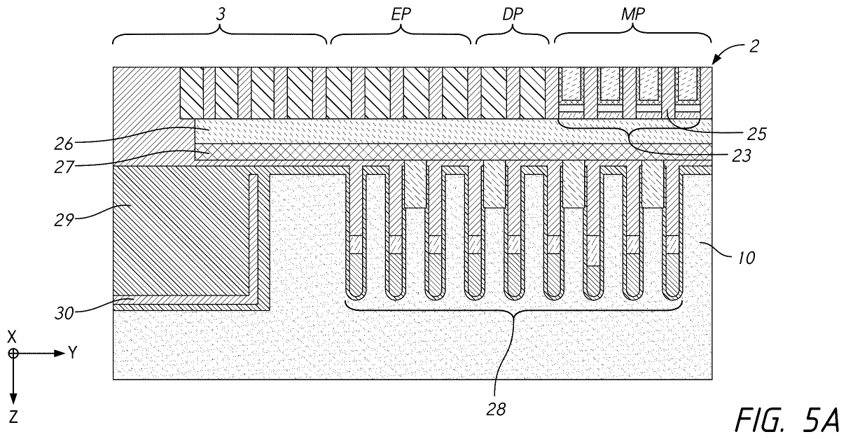

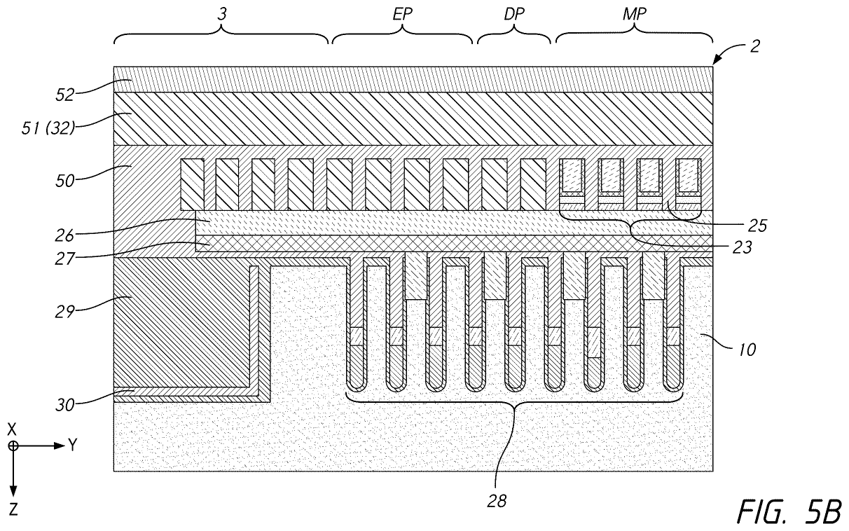

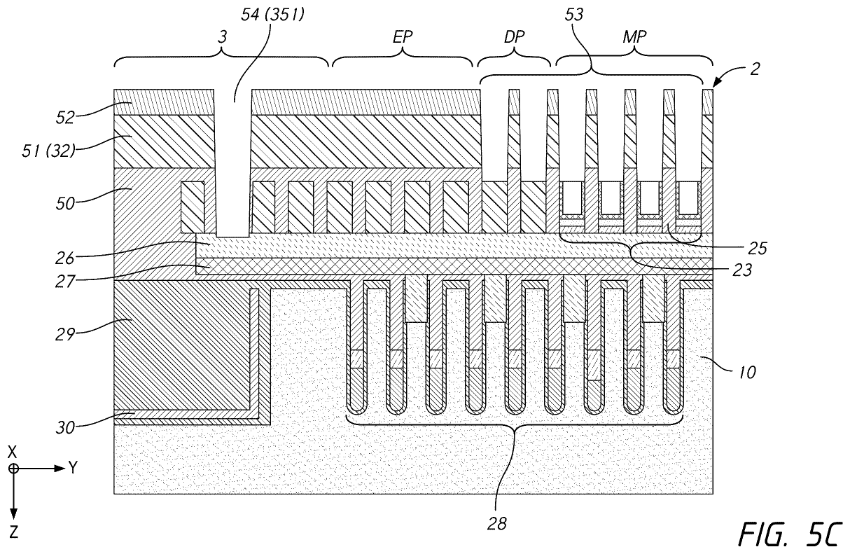

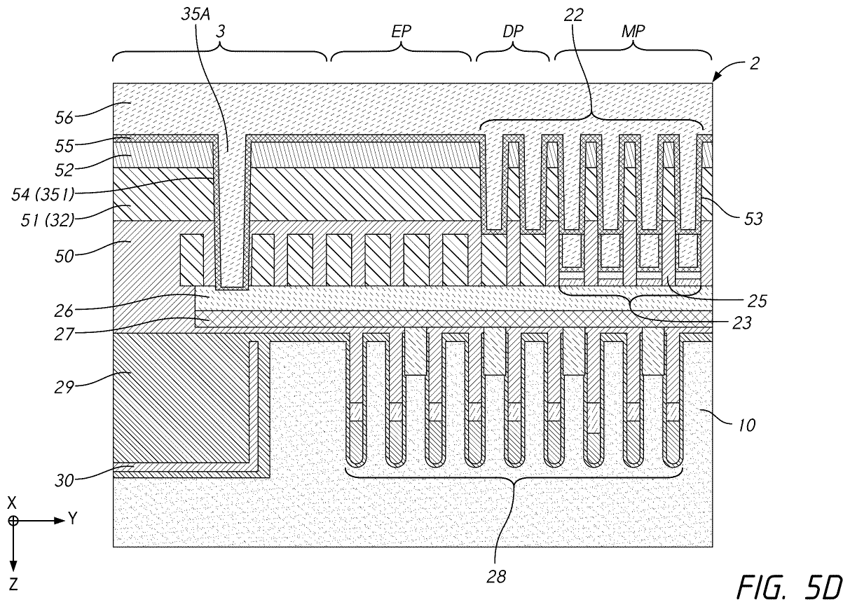

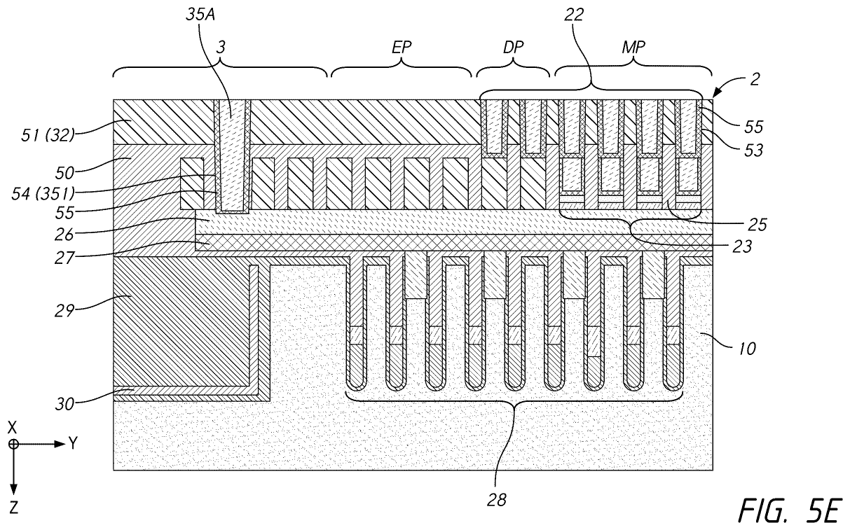

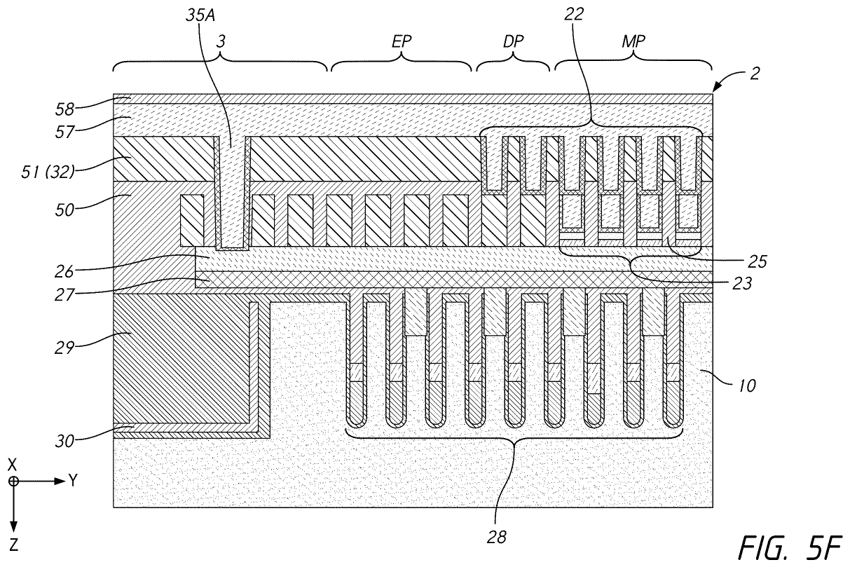

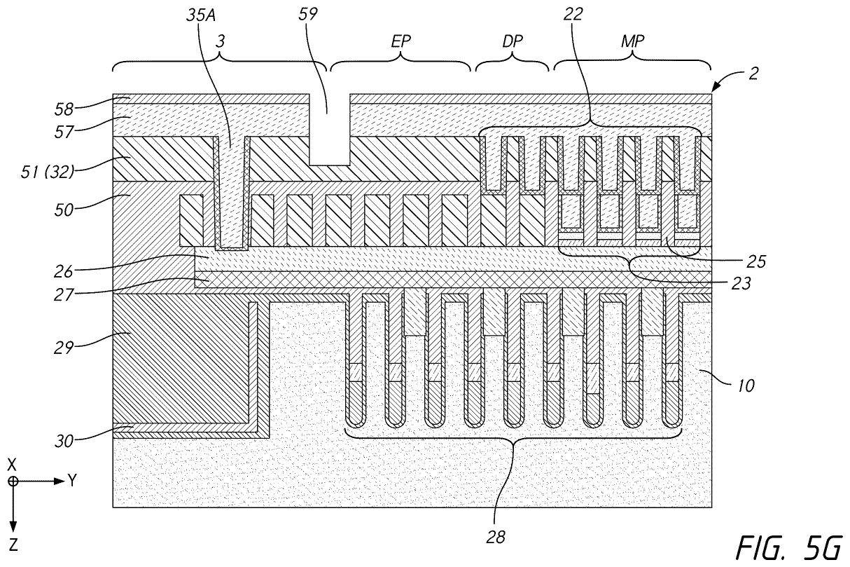

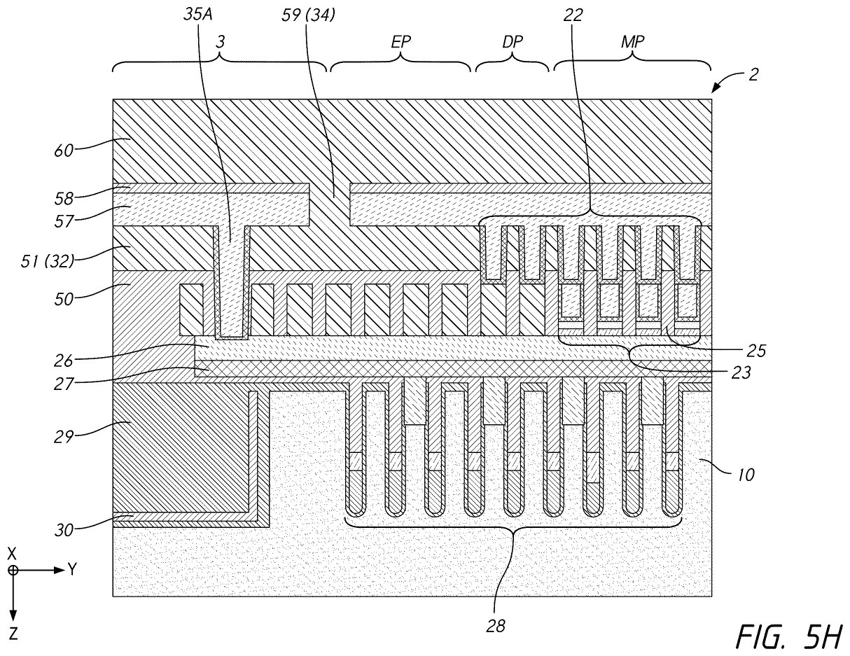

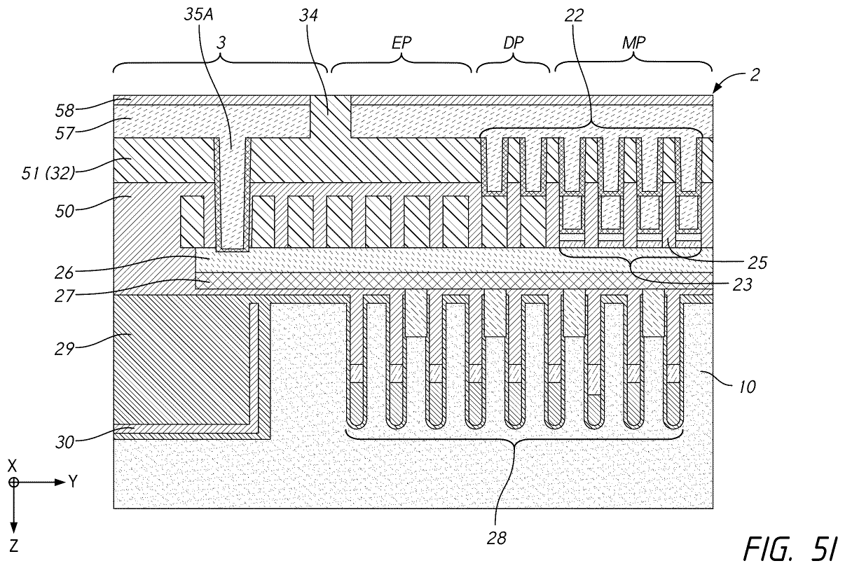

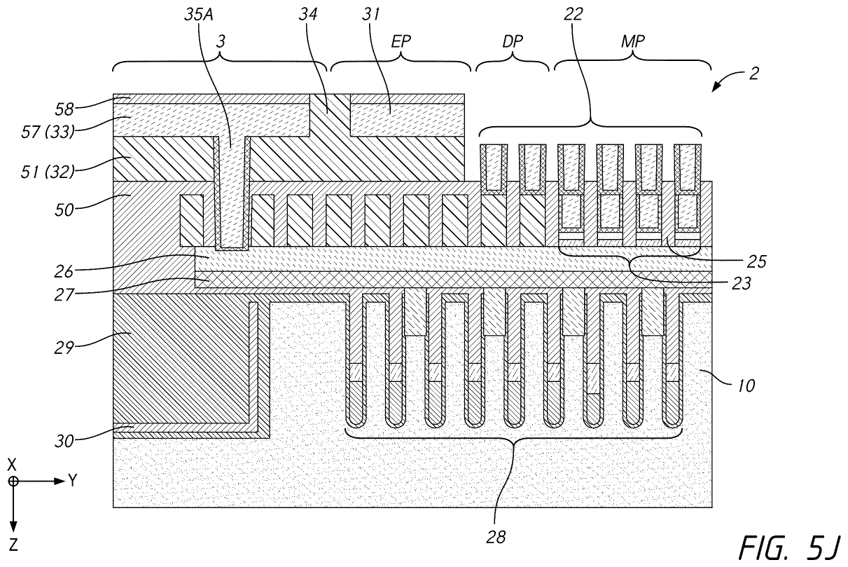

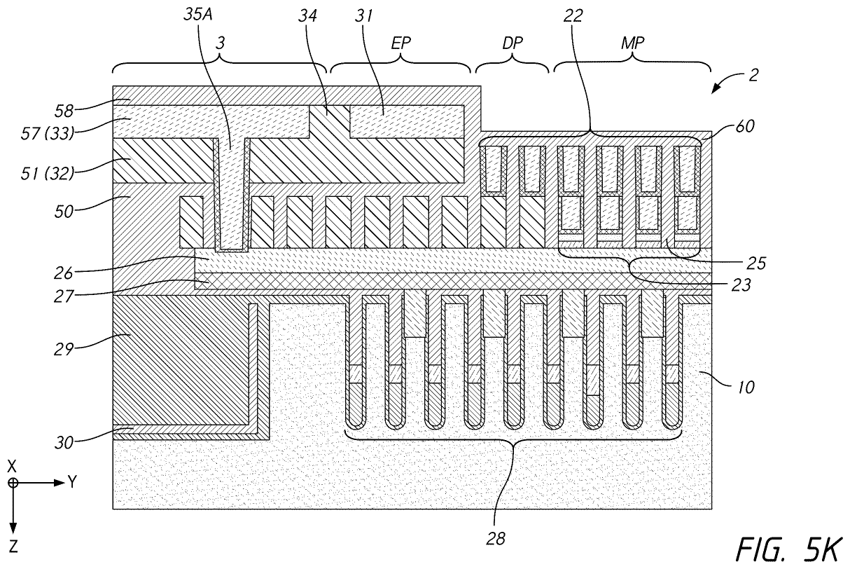

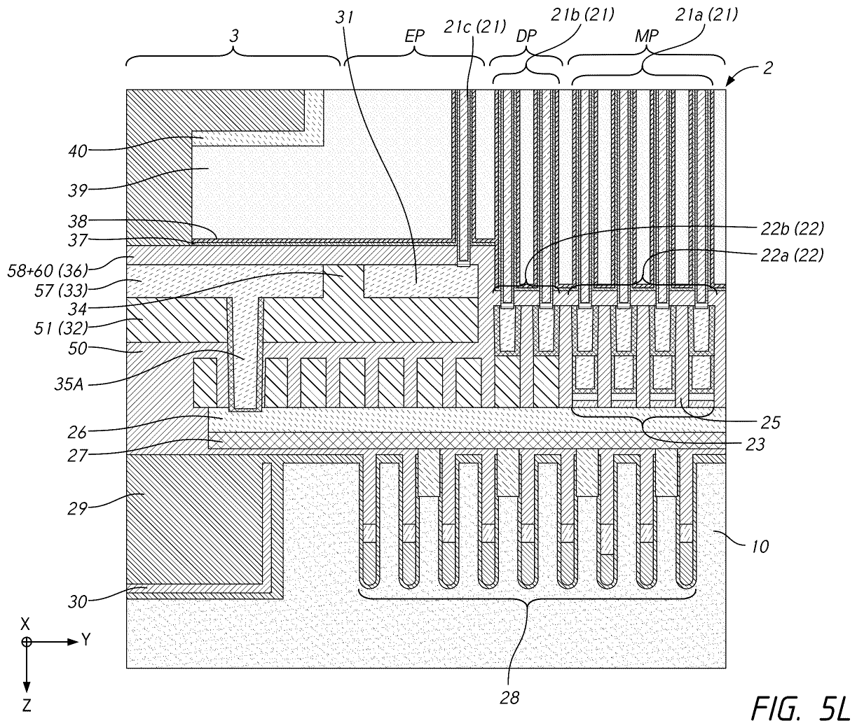

FIGS. 5A-5L depict example processes of manufacturing an example memory mat edge structure of a semiconductor device in a cross-sectional view according to an embodiment of the disclosure. The edge structure of the memory mat 2 as well as the neighboring peripheral region 3 manufactured by the processes of FIGS. 5A-5L correspond to those in FIG. 3A.

First, as shown in FIG. 5A, a part of the edge structure of the memory mat 2 as well as a part of the peripheral region 3 are formed in and/or on the semiconductor substrate 10, including the WL structures 28 in the memory cell, dummy and edge portions MP, DP and EP, the conductive layer 27 and the bit line 26 over the WL structures 28 extending from the memory mat 2 to the peripheral region 3, and the cell contact structures 23 in the memory cell portion MP, as well as the insulating layers 29 and 30, and the like in the peripheral region 3. Conventional methods, such as various deposition, etching, polishing, and photolithography, with conventional tools and materials may be used as appropriate.

Next, as shown in FIGS. 5B-5E, the plurality of RDL structures 23 are formed at respective predetermined positions in the memory cell and dummy portions MP and DP. In the memory cell portion MP, the predetermined positions correspond to at least the respective cell contact structures 23. First, an insulating layer 50 (such as a nitride layer), another insulating layer 51 (such as an oxide layer), and still another insulating layer 52 (such as a nitride layer) are provided, in that order, across the memory cell, dummy and edge portions MP, DP and EP and the peripheral region 3 by, for example, deposition (FIG. 5B). Then, a plurality of RDL holes 53, which are separate from each other, are formed at the respective predetermined positions in the memory cell and dummy portions MP and DP by, for example, etching corresponding parts of the stacked layers 50, 51 and 52 (FIG. 5C). At least the RDL holes 53 in the memory cell portion MP reach the cell contact structure 23. In the example, a local contact hole 54, which is separate from the RDL holes 53, is also formed at a predetermined position in the peripheral region 3 by, for example, etching corresponding parts of the stacked layers 50, 51 and 52 (FIG. 5C). The local contact hole 54 reaches the bit line 26. The local contact hole 54 corresponds to the contact hole 351 in FIG. 3A. The insulating layer 51 corresponds to the underlying insulating layer 32 in FIG. 3A. Subsequently, a conductive layer 55 (such as a titanium nitride layer) is provided to cover the surfaces of the RDL holes 53 and the local contact hole 54, and another conductive layer 56 (such as a tungsten layer) is provided to fill the RDL holes 53 and the local contact hole 54 (FIG. 5D) by, for example, deposition, thereby forming the RDL structures 22 in the memory cell and dummy portions MP and DP and the local contact structure 35A in the peripheral region 3. To further shape the RDL structures 22 and the local contact structure 35A, the residual conductive layers 55 and 56 as well as the underlying, insulating layer 52 are removed by, for example, chemical mechanical polishing (CMP) (FIG. 5E). The etching and the deposition may be part of a damascene process, and the CMP follows the damascene process. For the described processes herein, conventional etching, deposition, and polishing methods may be used as appropriate. Conventional photolithography methods may also be used as appropriate. While neither FIG. 3A nor FIG. 3B illustrates the conductive layer 55, the RDL structures 22 in FIGS. 3A and 3B may include the conductive layer 55 on the surfaces of the RDL holes thereof in a similar manner to the RDL structures 22 in FIGS. 5D and 5E.

Next, as shown in FIGS. 5F-5K, the moat structure 31 is formed at a predetermined position in the edge portion EP and at a higher layer level than the RDL structures 22 in the memory cell and dummy portions MP and DP. First, a conductive layer 57 (such as a tungsten layer) and an insulating layer 58 (such as a nitride layer) are provided across the memory cell, dummy and edge portions MP, DP and EP and the peripheral region 3 by, for example, deposition (FIG. 5F). Then, a part of the stacked layers 57 and 58 as well as a part of the insulating layer 51 in the edge portion EP are removed by, for example, etching, to form a hole 59 that penetrates the stacked layers 57 and 58 and reaches a certain depth in the insulating layer 51. The hole 59 separates at least a part of the edge portion EP from the peripheral region 3 (FIG. 5G). The separated part of the edge portion EP adjacent to the dummy portion DP will form the moat structure 31 through later processes. Subsequently, another insulating layer 60 (such as another oxide layer) is provided on surfaces of the edge portion EP as well as the memory cell and dummy portions MP and DP by, for example, deposition, to fill the hole 59 (FIG. 5H). The filled hole 59 corresponds to the gap 34 in FIG. 3. The residual insulating layer 60 is removed by, for example, etching, to expose surfaces of the insulating layer 58 and a top surface of the gap 34 (FIG. 5I). Then, parts of the stacked layers 51, 57 and 58 in the memory cell and dummy portions MP and DP are removed by, for example, etching (FIG. 5J). This reveals the RDL structures 22 in both the memory cell portion MP and the dummy portion DP at a lower layer level than the stacked layers 57 and 58 in the edge portion EP. The part of the conductive layer 57 in the edge portion EP separated from the rest of the conductive layer 57 by the gap 34 in the edge portion EP forms the moat structure 31 at a position higher than the RDL structures 22, and hence, the moat structure 31 is provided in the layer different from and higher than the layer of the RDL structures 22 on the semiconductor substrate 10. Accordingly, in comparison with the case where the moat structure 31 is formed in the same layer as the RDL structures 22, the critical dimension margin of the moat structure 31 is improved, and the likelihood of forming a defective moat structure is reduced, thereby preventing an issue like a short between the moat structure 31 and the RDL structures. Subsequently, an additional insulating layer 60 is provided across the memory cell, dummy and edge portions MP, DP and EP to cover the exposed surfaces of the RDL structures 22 and the moat structure 31 as well as the rest of the exposed surfaces of the memory mat edge structure including the surfaces of the gap 34 and the peripheral region 3 (FIG. 5K). In the example, the part of the conductive layer 57 in the peripheral region 3 separated from the moat structure 31 in the edge portion EP corresponds to the conductive layer structure 33 in FIG. 3A. For the described processes herein, conventional etching, deposition, and polishing methods may be used as appropriate. Conventional photolithography methods may also be used as appropriate.

Finally, as shown in FIG. 5L, the capacitor structures 21 (21a, 21b, and 21c) are formed at the positions corresponding to the RDL structures 22 (22a and 22b) in the memory cell and dummy portions MP and DP such that the capacitor structures 21 are coupled to the RDL structures 22, respectively. Furthermore, the outermost capacitor structure 21c among the plurality of capacitor structures 21 is formed at the position corresponding to the moat structure 31 in the edge portion EP. The outermost capacitor structure 21c is coupled to the moat structure 31. Although only one outermost capacitor structure 21c is illustrated in the drawing of the cross-sectional view, the edge portion EP may include the plurality of outermost capacitor structures along the periphery of the dummy portion DP in the X and Y-axes plane as shown in the plan view of FIG. 2, and the plurality of outermost capacitor structures may be coupled to the moat structure MS (FIG. 2)/31 (FIG. 5L) which is formed around the dummy portion DP.

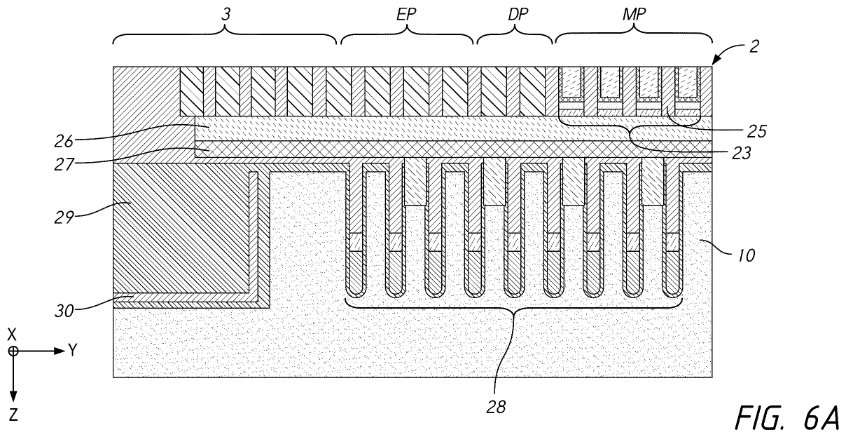

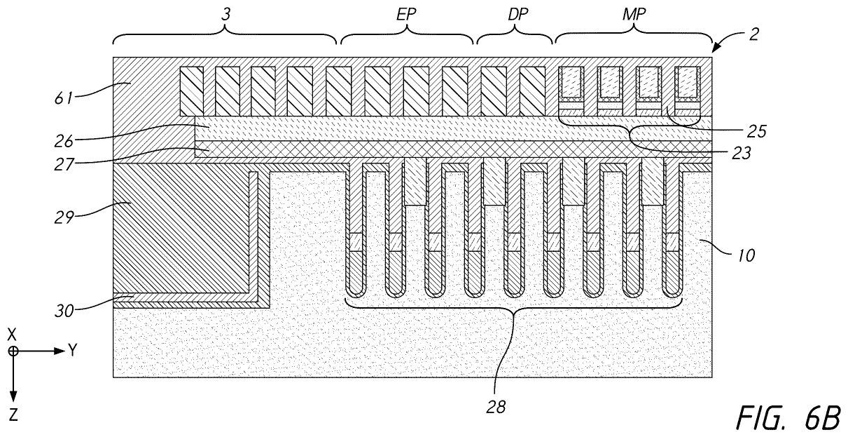

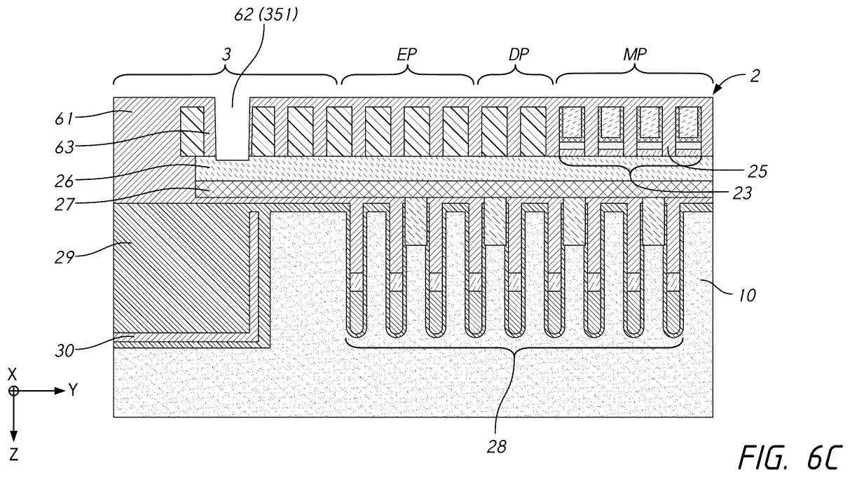

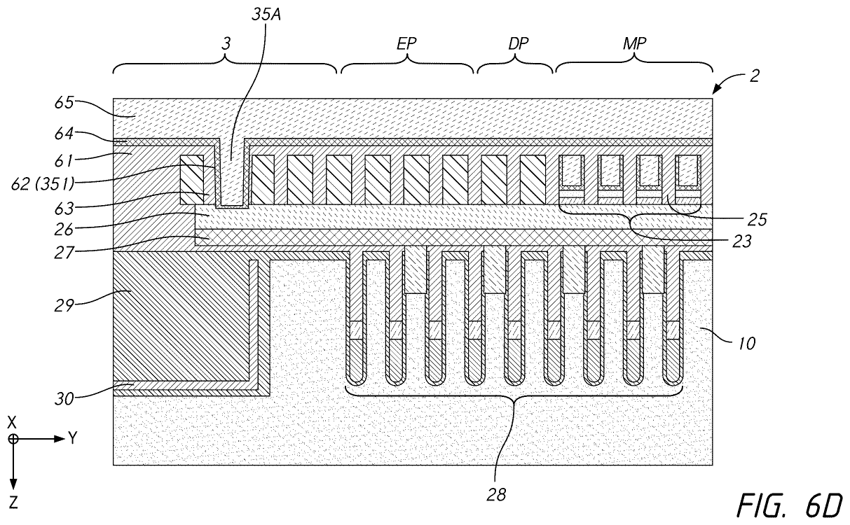

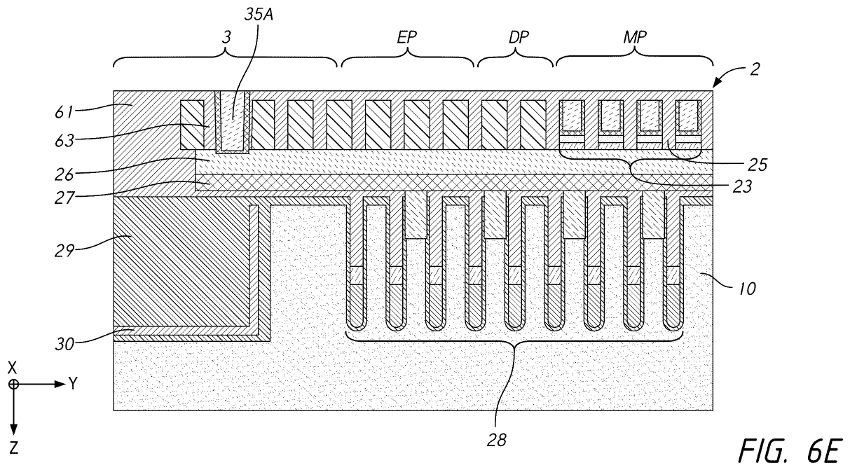

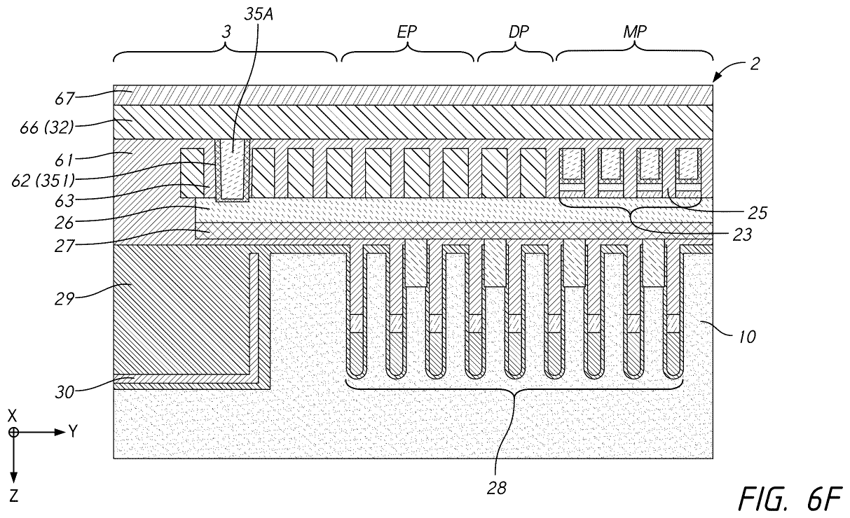

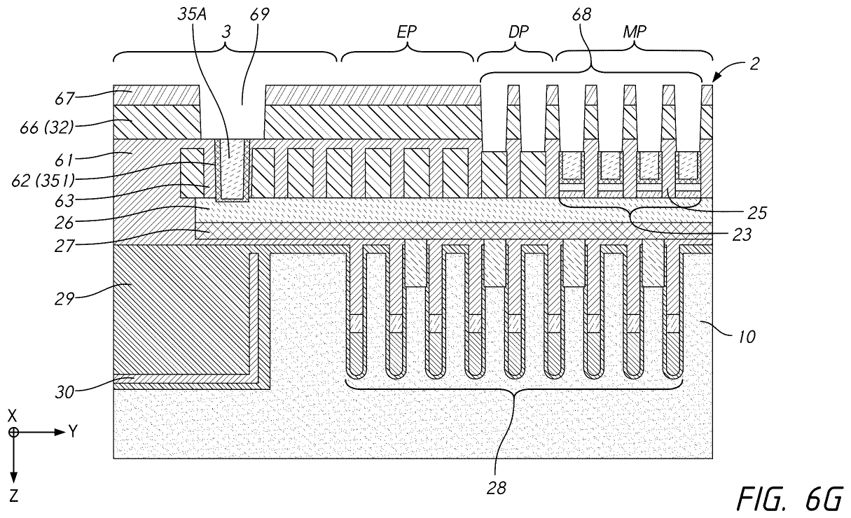

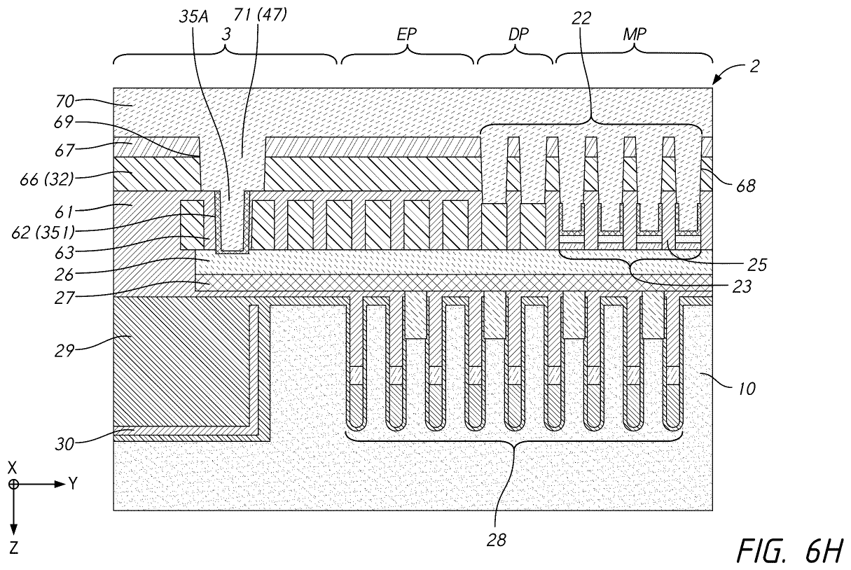

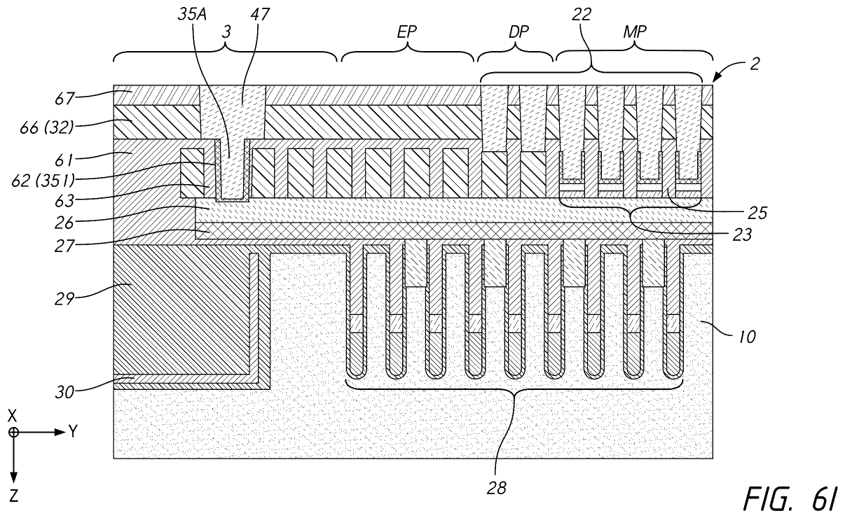

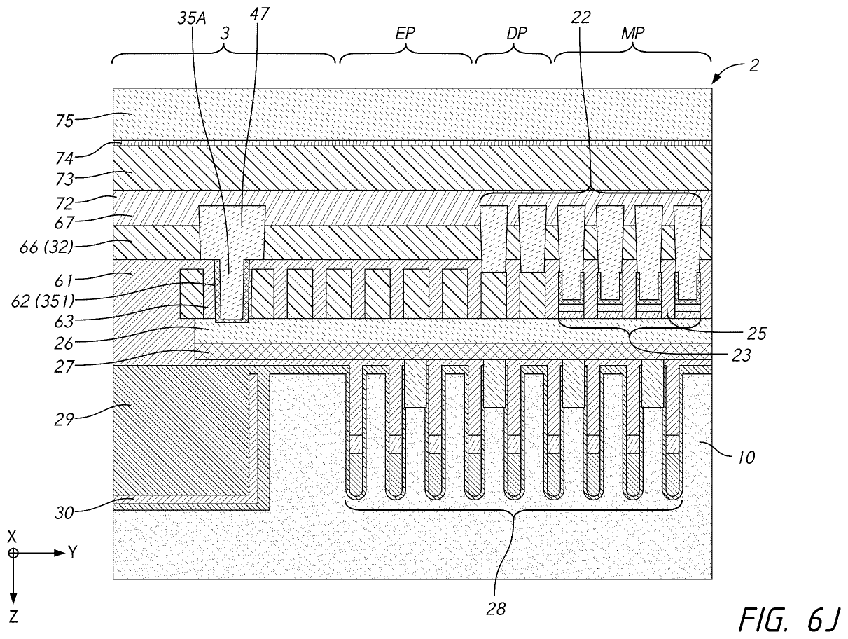

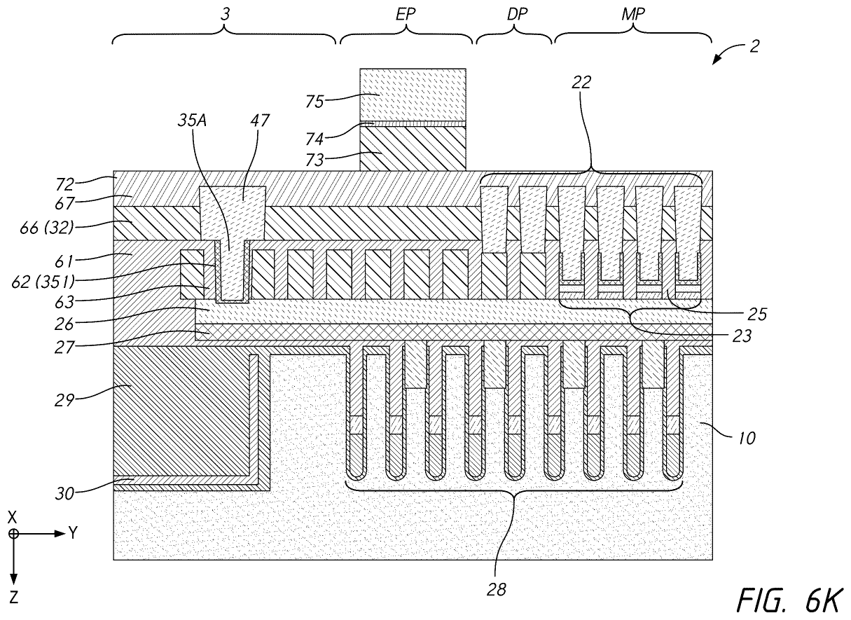

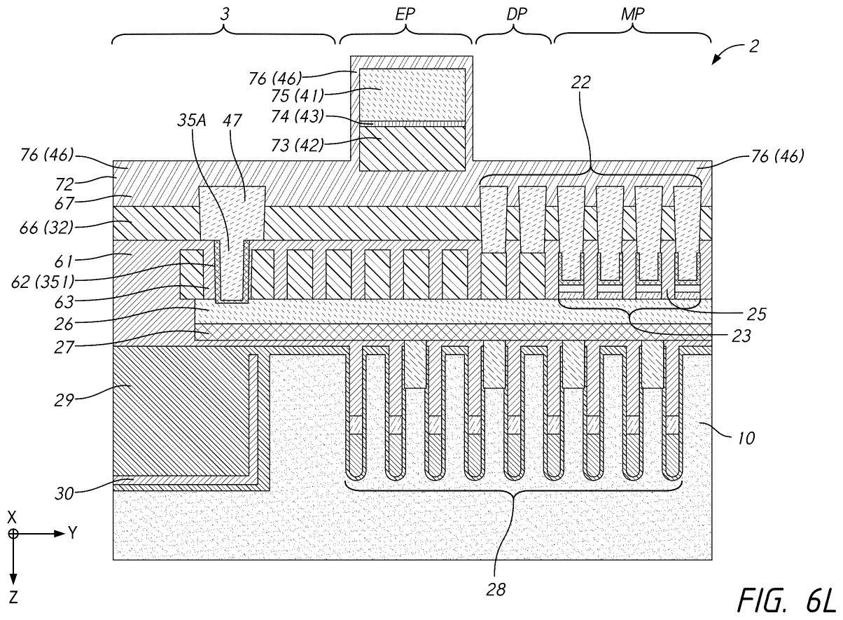

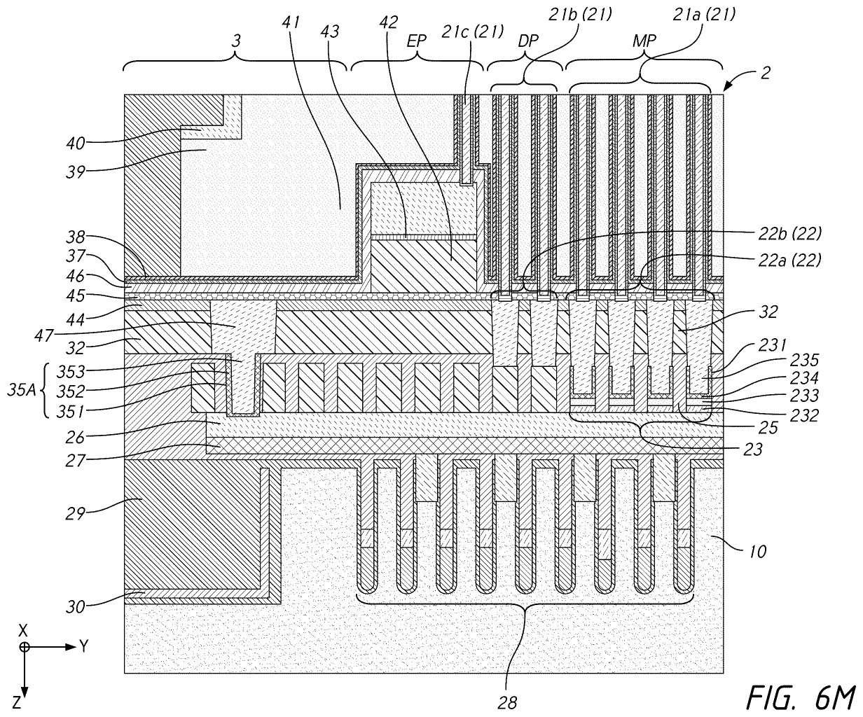

FIGS. 6A-6M depict example processes of manufacturing an example memory mat edge structure of a semiconductor device in a cross-sectional view according to an embodiment of the disclosure. The memory mat edge structure manufactured by the processes of FIGS. 6A-6M correspond to the edge structure of the memory mat 2 in FIG. 4A.

First, in a similar manner to the example of FIG. 5A, as shown in FIG. 6A, a part of the memory mat edge structure, that is the edge structure of the memory mat 2, as well as a part of the peripheral region 3 are formed in and/or on the semiconductor substrate 10, including the WL structures 28 in the memory cell, dummy and edge portions MP, DP and EP, the conductive layer 27 and the bit line 26 over the WL structures 28 extending from the memory mat 2 to the peripheral region 3, and the BL construct structures 23 above the bit line 26 in the memory cell portion MP, as well as the insulating layers 29 and 30, and the like in the peripheral region 3. Conventional methods, such as various deposition, etching, polishing, and photolithography, with conventional tools and materials may be used as appropriate.

Next, as shown in FIGS. 6B-6E, a local contact structure 35 is formed at a predetermined position in the peripheral region 3. First, an insulating layer 61 (such as a nitride layer) is provided across the memory cell, dummy and edge portions MP, DP and EP and the peripheral region 3 by, for example, deposition (FIG. 6B). Then, a local contact hole 62 is formed at a predetermined position in the peripheral region 3 by, for example, etching, corresponding parts of the insulating layer 61 and an underlying structure 63 (FIG. 6C). The local contact hole 62 reaches the bit line 26. The local contact hole 62 corresponds to the contact hole 351 in FIG. 4A. Subsequently, a conductive layer 64 (such as a titanium nitride layer) is provided to cover the exposed surfaces of the local contact hole 62, and another conductive layer 65 (such as a tungsten layer) is provided to fill the local contact hole 62 by, for example, deposition, thereby forming the local contact structure 35A in the peripheral region 3 (FIG. 6D). To further shape the local contact structure 35A, the residual conductive layers 64 and 65 are removed by, for example, chemical mechanical polishing (CMP) (FIG. 6E). The etching and the deposition may be part of a damascene process, and the CMP follows the damascene process. For the described processes herein, conventional etching, deposition, and polishing methods may be used as appropriate. Conventional photolithography methods may also be used as appropriate.

Next, as shown in FIGS. 6F-I, the plurality of RDL structures 22 are formed at respective predetermined positions in the memory cell and dummy portions MP and DP. In the memory cell portion MP, the predetermined positions correspond to at least the respective cell contact structures 23. First, an insulating layer 66 (such as an oxide layer) and another insulating layer 67 (such as a nitride layer) are provided across the memory cell, dummy and edge portions MP, DP and EP and the peripheral region 3 by, for example, deposition (FIG. 6F). The insulating layer 66 corresponds to the underlying insulating layer 32 in FIG. 4A. Then, a plurality of RDL holes 68, which are separate from each other, are formed at the respective predetermined positions in the memory cell and dummy portions MP and DP by, for example, etching corresponding parts of the stacked layers 66 and 67 and the underlying insulating layer 61 (FIG. 6G). Top portions of the respective cell contact structures 23 may also be etched as appropriate. This way, at least the RDL holes 68 in the memory cell portion MP reach the cell contact structures 23. In the example, another part of the stacked layers 66 and 67 is also removed in the peripheral region 3 by, for example, etching, to form a hole 69 (FIG. 6G). Subsequently, a conductive layer 70 (such as a tungsten layer) is provided to fill the RDL holes 68 in the memory cell and dummy portions MP and DP and the hole 69 in the peripheral region 3 (FIG. 6H), and the residual conductive layer 70 is removed by CMP (FIG. 6I). The filled RDL holes 68 form the RDL structures 22 in the memory cell and dummy portions MP and DP. Only the RDL structures 22 in the memory cell portion MP are coupled to the cell contact structures 23. The filled hole 69 forms a conductive layer structure 71 in the peripheral region 3, being coupled to the local contact structure 35A. The conductive layer structure 71 corresponds to the conductive layer structure 47 in FIG. 4A. Hence, the RDL structures 22 are coupled to the cell contact structures 23 in the memory cell portion MP, and the conductive layer structure 47 is coupled to the local contact structure 35 in the peripheral region 3. The etching and the deposition may be part of a damascene process, and the CMP process follows the damascene process. In the example, thus, the RDL structures 22 and the conductive layer structure 41 are formed in the same layer by the damascene process, followed by the CMP process. For the described processes herein, conventional etching, deposition, and polishing methods may be used as appropriate. Conventional photolithography methods may also be used as appropriate.

Next, as shown in FIGS. 6J-6L, the moat structure 41 is provided at a predetermined position in the edge portion EP and at a higher layer level than the RDL structures 22 in the memory cell and dummy portions MP and DP. First, an insulating layer 72 (such as a nitride layer), another insulating layer 73 (such as an oxide layer), a conductive layer 74 (such as a titanium nitride layer), and another conductive layer 75 (such as a tungsten layer) are provided, in that order, across the memory cell, dummy and edge portions MP, DP and EP and the peripheral region 3 by, for example, deposition (FIG. 6J). Then, parts of the stacked layers 73, 74 and 75 in the memory cell, dummy and edge portions MP, DP and EP and the peripheral region 3 are removed by, for example, etching, to leave a predetermined part of the stacked layers 73-75 at a predetermined position on the underlying insulting layer 72 in the edge portion EP (FIG. 6K). Subsequently, another insulating layer 76 (such as a nitride layer) is provided to cover the exposed surfaces across the memory cell, dummy and edge portions MP, DP and EP and the peripheral region 3 (FIG. 6L). The parts of the stacked layers 73-75 left on the underlying insulating layer 72 and covered by the insulating layer 76 correspond to the underlying layer structure 42, the middle thin film 43, and the moat structure 41 in FIG. 4A, respectively. The insulating layer 76 corresponds to the insulating layer 46 in FIG. 4A. According to the present embodiment, since the moat structure 41 is formed in the layer above the layer where at least the underlying layer structure 42 is formed and further above the layer where at least the RDL structures 22 and the conductive layer structure 47 are formed, the critical dimension margin of the moat structure 31 is further improved, and defective formation of the moat structure 31 that may cause an issue such as a short between the moat structure 31 and the conductive elements at lower layer levels can be further effectively prevented. For the described processes herein, conventional etching, deposition, and polishing methods may be used as appropriate. Conventional photolithography methods may also be used as appropriate.

Finally, as shown in FIG. 6M, the capacitor structures 21 (21a, 21b, and 21c) are formed at the positions corresponding to the RDL structures 22 (22a and 22b) in the memory cell and dummy portions MP and DP such that the capacitor structures 21 are coupled to the RDL structures 22, respectively. Furthermore, the outermost capacitor structure 21c among the plurality of capacitor structures 21 is formed at the position corresponding to the moat structure 41 in the edge portion EP. The outermost capacitor structure 21c is coupled to the moat structure 41. Although only one outermost capacitor structure 21c is illustrated in the drawing of the cross-sectional view, the edge portion EP may include the plurality of outermost capacitor structures along the periphery of the dummy portion DP in the X and Y-axes plane as shown in the plan view of FIG. 2, and the plurality of outermost capacitor structures may be coupled to the moat structure MS (FIG. 2)/41 (FIG. 6M) which is formed around the dummy portion DP. Lastly, FIG. 6M shows the insulating layers 44 and 45 in place of the insulating layers 67 and 72 in FIG. 6L above the insulating layers 66/32. This is simply one of variations of the layer structure.

One example of the semiconductor device 1 may be a DRAM. However, a DRAM is merely one example, and the embodiments and the descriptions herein are not intended to be limited to a DRAM. Memory devices other than a DRAM, such as a static random-access memory (SRAM), a flash memory, an erasable programmable read-only memory (EPROM), a magnetoresistive random-access memory (MRAM), and a phase-change memory, can also be applied as the semiconductor device 1. Furthermore, devices other than memory devices, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a memory mat including a plurality of capacitor structures on a semiconductor substrate, the memory mat further including a memory cell portion, a dummy portion adjacent to the memory cell portion, and an edge portion adjacent to the dummy portion, wherein
the memory cell portion includes a first capacitor structure of the plurality of capacitor structures, a first redistribution layer structure coupled to the first capacitor structure, and a cell contact structure coupled to the redistribution layer structure, and the first capacitor structure is coupled to the cell contact structure by the first redistribution layer structure,
the dummy portion includes a second capacitor structure of the plurality of capacitor structures and a second redistribution layer structure coupled to the second capacitor structure, and
the edge portion includes an outermost capacitor structure of the plurality of capacitor structures and a conductive layer structure coupled to the outermost capacitor structure, and the conductive layer structure is at a position higher than the first and second redistribution layer structures on the semiconductor substrate.

2. The apparatus according to claim 1, wherein the conductive layer structure is at a higher layer level than the first and second redistribution layer structures on the semiconductor substrate.

3. The apparatus according to claim 1, wherein
the cell contact structure is in a first layer,
the first and second redistribution layer structures are in a second layer above the first layer, and
the conductive layer structure is in a third layer above the second layer.

4. The apparatus according to claim 1, wherein the first and second redistribution layer structures include tungsten, and the conductive layer structure includes tungsten.

5. The apparatus according to claim 1, wherein
the edge portion further includes an underlying layer structure below the conductive layer structure, and
the conductive layer structure on the underlying layer structure is at a position further higher than the first and second redistribution layer structures on the semiconductor substrate.

6. The apparatus according to claim 5, wherein the conductive layer structure on the underling layer structure is at a further higher layer level than the first and second redistribution layer structures on the semiconductor substrate.

7. The apparatus according to claim 5, wherein the first and second redistribution layer structures include tungsten, the conductive layer structure includes tungsten, and the underlying layer structure includes an oxide.

8. The apparatus according to claim 1, wherein the conductive layer structure in the edge portion is not coupled to the first redistribution layer structure and the cell contact structure in the memory cell portion and the second redistribution layer structure in the dummy portion.

9. The apparatus according to claim 1, wherein the conductive layer structure in the edge portion is adjacent to the dummy portion.

10. The apparatus according to claim 1, wherein the memory mat has a rectangular shape, and the conductive layer structure extends around a rectangular periphery of the memory mat.

11. The apparatus according to claim 1, wherein
in the memory cell portion, the first capacitor structure include a first plurality of capacitor structures, the first redistribution layer structure includes a first plurality of redistribution layer structures, the cell contact structure includes a plurality of cell contact structures, and the first plurality of capacitor structures are coupled to the plurality of cell contact structures by the first plurality of redistribution layer structures, respectively,
in the dummy portion, the second capacitor structure includes a second plurality of capacitor structures, and the second redistribution layer structure includes a second plurality of redistribution layer structures coupled to the second plurality of capacitor structures, and
in the edge portion, the outermost capacitor structure includes a plurality of outermost capacitor structures coupled to the conductive layer structure.

12. The apparatus according to claim 1, wherein
the memory mat is a first memory mat, and
the apparatus comprises a plurality of memory mats including the first memory mat arranged in a matrix on the semiconductor substrate, each of the plurality of memory mats including the memory cell portion, the dummy portion, and the edge portion.

13. An apparatus, comprising a memory mat including a plurality of capacitor structures arranged in a matrix on a semiconductor substrate, the memory mat further including a memory cell portion, a dummy portion adjacent to and surrounding the memory cell portion, and an edge portion adjacent to and surrounding the dummy portion, wherein
the memory cell portion includes a first capacitor structure of the plurality of capacitor structures, a first redistribution layer structure coupled to the first capacitor structure, and a cell contact structure coupled to the redistribution layer structure, and the first capacitor structure is coupled to the cell contact structure by the first redistribution layer structure,
the dummy portion includes a second capacitor structure of the plurality of capacitor structures and a second redistribution layer structure coupled to the second capacitor structure,
the edge portion includes an outermost capacitor structure of the plurality of capacitor structures and a conductive layer structure coupled to the outermost capacitor structure, and
the cell contact structure is in a first layer, the first and second redistribution layer structures are in a second layer above the first layer, and the conductive layer structure is in a third layer above the second layer on the semiconductor substrate.

14. The apparatus according to claim 13, wherein the second layer includes a conductive layer, and the third layer includes another conductive layer.

15. The apparatus according to claim 13, wherein the edge portion further includes an underlying layer structure in a fourth layer between the second layer and the third layer, and the conductive layer structure is on the underlying layer structure.

16. The apparatus according to claim 15, wherein the second layer includes a conductive layer, the third layer includes another conductive layer, and the fourth layer includes an insulating layer.

17. The apparatus according to claim 13, wherein the conductive layer structure of the edge portion is adjacent to the dummy portion and surrounds the dummy portion.

18. An apparatus, comprising a memory mat including a memory cell portion, a dummy portion surrounding the memory cell portion, and an edge portion surrounding the dummy portion on a semiconductor substrate, wherein
the memory cell portion includes a first group of capacitor structures, a first group of redistribution layer structures, and a group of cell contact structures, and the first group of capacitor structures is coupled to the group of cell contact structures by the first group of redistribution layer structures,
the dummy portion includes a second group of capacitor structures and a second group of redistribution layer structures, and the second group of capacitor structures is coupled to the second group of redistribution layer structures,
the edge portion includes a third group of capacitor structures and a conductive layer structure, and the third group of capacitor structures is coupled to the conductive layer structure, and
the conductive layer structure of the edge portion is in a first layer higher than a second layer on the semiconductor substrate, the second layer including the first and second groups of redistribution layer structures of the memory cell and dummy portions.

19. The apparatus according to claim 18, wherein the conductive layer structure is on an insulating layer structure in a third layer, and the third layer is below the first layer and above the second layer.

20. The apparatus according to claim 18. wherein the conductive layer structure of the edge portion surrounds the dummy portion.
